(19) United States
(12) Patent Application Publication
(10) Pub. No.: US 2022/0361356 A1
(43) Pub. Date: Nov. 10, 2022

(54) ELECTRONIC SYSTEM WITH ELECTRONIC MEASURING DEVICE AND COMPRISING A SEAL AND AN ELECTRICAL ASSEMBLY INCLUDING SUCH AN ELECTRONIC SYSTEM

(71) Applicant: VALEO EQUIPEMENTS ELECTRIQUES MOTEUR, Creteil Cedex (FR)

(72) Inventors: Frederic SCHEITEL, Creteil Cedex (FR); Charles DUMEZ, Creteil Cedex (FR); Manuel FALGUIER, Creteil Cedex (FR); Michael SANCHES, Creteil Cedex (FR)

(73) Assignee: VALEO EQUIPEMENTS ELECTRIQUES MOTEUR, Creteil Cedex (FR)

(21) Appl. No.: 17/620,965

(22) PCT Filed: Jun. 9, 2020
(86) PCT No.: PCT/EP2020/065958

§ 371 Date: Dec. 20, 2021

(30) Foreign Application Priority Data
Jun. 21, 2019 (FR) FR1906760

(51) Int. Cl. H05K 7/14

(52) U.S. Cl. CPC H05K 7/14329; H05K 7/1469

(57) ABSTRACT

An electronic system includes a power electronics module for converting a DC current to an AC current. The power electronics module includes a first busbar and a second busbar for supplying the power electronics module with the DC current, a third busbar able to supply a phase winding of a rotating electric machine, and a control pin receiving a control signal for driving the power electronics module. An electronic control module separate from the power electronics module is configured so as to generate the control signal. The electronic control module includes an electronic measuring device, a support including an opening and carrying the electronic control module on a first side of the support, a measurement housing including a cavity, the measurement housing being located on a second side of the support opposite the first side of the support. The electronic measuring device penetrates into the opening in the support and into the cavity in the measurement housing. A sealing means providing a seal between the measurement housing and the support.

The invention relates to an electronic system, in particular an electronic control system for a rotating electric machine, comprising a measuring device and comprising a seal, and to an electrical assembly comprising such an electronic system and a rotating electric machine.

As is known, an electronic system may comprise:
a power electronics module for converting a DC current to an AC current, the power electronics module comprising:
   a first busbar and a second busbar for supplying the power electronics module with the DC current,
   a third busbar able to supply a phase winding of a rotating electric machine,
   a control pin receiving a control signal for driving the power electronics module,
an electronic control module separate from the power electronics module and configured so as to generate the control signal, the electronic control module comprising an electronic measuring device,
a support carrying the electronic control module on a first side of the support, the support comprising a protuberance on a second side of the support opposite the first side of the support,
a measurement housing comprising a slot, the housing being located on the second side of the support,

the electronic measuring device being housed in the protuberance of the support,

the protuberance penetrating into the cavity in the measurement housing such that the electronic measuring device also penetrates into the slot of the measurement housing.

The slot of the measurement housing may correspond to an air gap of a magnetic toroid contained in the measurement housing. Document FR3068564 A1 discloses one example of a measurement housing with a magnetic toroid. In that document, the measurement housing is overmolded onto the magnetic toroid.

The electronic measuring device is for example a Hall effect sensor. Such a Hall effect sensor penetrating into the air gap of the magnetic toroid makes it possible to measure the current flowing through a conductor passing through the magnetic toroid.

In this type of electronic system, it is important to protect the electronic control module, for example using a gel or a protective resin. It is known practice to use a support that defines a receptacle with a bottom wall in which the protuberance is formed, the electronic control module being housed in the receptacle. By virtue of the sealing of the protuberance, it is possible to fill the receptacle so as to cover the electronic control module with a gel or a protective resin.

Such a current measurement is possible if the support and its protuberance are made of plastic.

For reasons of mechanical strength and/or thermal and/or fire protection properties, the use of a metal support may be preferred. However, using a support with a metal protuberance makes measurement difficult. Specifically, eddy currents are induced at high frequency in the metal of the support and its protuberance. These eddy currents cause interference in the measurement.

The present invention seeks to overcome all or some of these disadvantages.

The invention relates to an electronic system comprising:
a power electronics module for converting a DC current to an AC current, the power electronics module comprising:
   a first busbar and a second busbar for supplying the power electronics module with the DC current,
   a third busbar able to supply a phase winding of a rotating electric machine,
   a control pin receiving a control signal for driving the power electronics module,
an electronic control module separate from the power electronics module and configured so as to generate the control signal, the electronic control module comprising an electronic measuring device,
a support comprising an opening and carrying the electronic control module on a first side of the support, the support being in particular made of metal,
a measurement housing comprising a cavity, the measurement housing being located on a second side of the support opposite the first side of the support,

the electronic measuring device penetrating into the opening in the support and into the cavity in the measurement housing,

a sealing means providing a seal between the measurement housing and the support.

Such a system makes it possible, on the one hand, to use an electronic measuring device of an electronic control module carried by a support while reducing the interference that the support could create, in particular if the support is made of metal. Specifically, the opening in the support allows through a sensitive part of the electronic measuring device, such that the support does not interfere between the sensitive part and an element with which the sensitive part interacts. It is thus possible to use a measuring device whose sensitive part is a Hall effect sensor on a metal support, for example made of aluminum. Such a sensor is for example used to measure the current flowing through a conductor passing through a magnetic toroid with an air gap. The Hall effect sensor is then placed in the air gap. The absence of any metal part between the magnetic toroid and the Hall effect sensor makes it possible to avoid interference in the measurement that would be generated by eddy currents that would be induced at high frequency in such a metal part.

The sealing means between the measurement housing and the support makes it possible for example to use a protective means such as a protective gel for the electronic control module in the support, in spite the presence of the openings in the support.

According to one additional feature of the invention, the electronic module comprises a first casing overmolded onto the first busbar, the second busbar, the third busbar and the control pin, and the measurement housing is formed contiguously with the first overmolded casing of the power electronics module.

According to a first variant of the invention, the measurement housing comprises a chimney, comprising a first free end, surrounding an open end of the cavity, and the support comprises a groove facing the first free end of the chimney of the measurement housing.

According to a second variant of the invention, the support comprises a chimney, comprising a first free end, surrounding the opening in the support on the second side of the support, and the measurement housing comprises a groove facing the first free end of the chimney.

According to one additional feature of the invention, a seal inserted into the groove provides the seal between the measurement housing and the support.

According to one additional feature of the invention, the seal is an adhesive deposit.

The use of a groove makes it possible to facilitate the application of the seal to the support in the first variant of the invention and to the housing in the second variant of the invention. When handling components, the groove limits the movement of a solid seal such as an elastomer seal, or limits the flow of a fluid seal such as an adhesive.

According to a third variant of the invention:
either the measurement housing comprises a chimney, comprising a first free end of a first shape, surrounding an open end of the cavity, and the support comprises a bearing surface of a second shape, complementary to the first shape, facing the first free end of the chimney of the measurement housing,
or the support comprises a chimney, comprising a first free end of a first shape, surrounding the opening in the support on the second side of the support, and the measurement housing comprises a bearing face of a second shape, complementary to the first shape, facing the first free end of the chimney of the support,
or the support comprises a first chimney, comprising a first free end of a first shape, surrounding the opening in the support on the second side of the support, and the measurement housing comprises a second chimney, comprising a second free end of a second shape complementary to the first shape, surrounding an open end of the cavity, the second free end of the second chimney of the measurement housing facing the first free end of the first chimney of the support,

a seal being arranged between the first shape of the support and the second shape of the measurement housing.

The use of complementary shapes between the support and the measurement housing makes it possible to use simple flat seals or seals made of a small amount of paste. It is thus possible to reduce the cost of the electronic system.

According to a fourth variant of the invention, the support comprises a first tubular protuberance surrounding the opening in the support on the second side of the support, and the measurement housing comprises a second tubular protuberance at least partially around the cavity, the first tubular protuberance penetrating into the second tubular protuberance.

According to one additional feature of the fourth variant of the invention, a sealing device is arranged between the first tubular protuberance and the second tubular protuberance.

According to one additional feature of the fourth variant of the invention, the sealing device is a resin that is poured into the cavity and then polymerized.

The use of a resin to provide the seal between the support and the measurement housing allows wider dimensional tolerances on the areas between which the seal is produced. Specifically, the fluidity of the resin before it polymerizes allows good matching to components in contact with the resin. It is therefore possible to have wide tolerances on the dimensions of the first tubular protuberance and of the second tubular protuberance. It is thus possible to reduce the cost of the electronic system.

According to one additional feature of the invention, the measurement housing comprises a magnetic toroid having an air gap, and the electronic measuring device comprises a Hall effect sensor inserted into the cavity in the measurement housing and the air gap, the magnetic toroid and the Hall effect sensor interacting so as to measure the current of an electrical conductor passing through the magnetic toroid.

According to one additional feature of the invention, the electrical conductor is electrically connected to the third busbar.

According to one additional feature of the invention, the measurement housing is overmolded onto the electrical conductor and/or the measurement housing is overmolded onto the magnetic toroid.

According to one additional feature of the invention, the support defines a receptacle with a bottom wall in which the opening is formed, the electronic control module is housed in the receptacle and a gel or a protective resin fills the receptacle so to cover the electronic control module.

The invention also relates to an electrical assembly comprising:
an electronic system as described above,
a rotating electric machine.

The invention may be better understood from reading the following description of non-limiting exemplary embodiments thereof and on studying the appended drawing, in which:

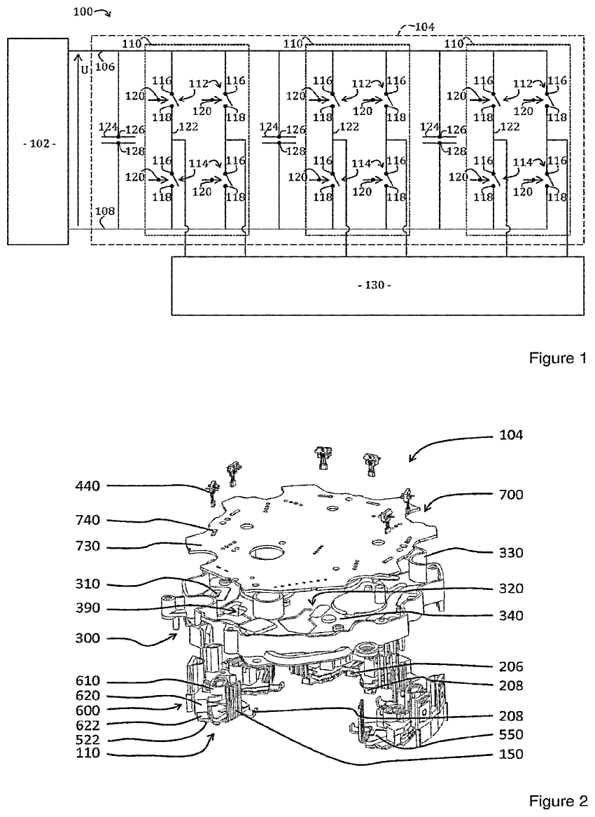

FIG. 1 shows a circuit diagram of an electrical assembly comprising an electronic system according to the invention,

FIG. 2 shows an exploded partial schematic view of an electronic system according to the invention,

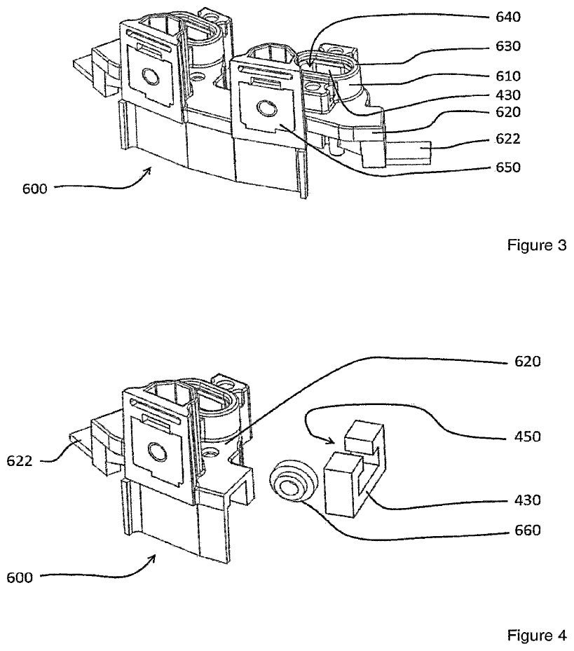

FIG. 3 shows a view of a measurement housing used in the electronic system of FIG. 2,

FIG. 4 shows a partial view of the measurement housing of FIG. 3,

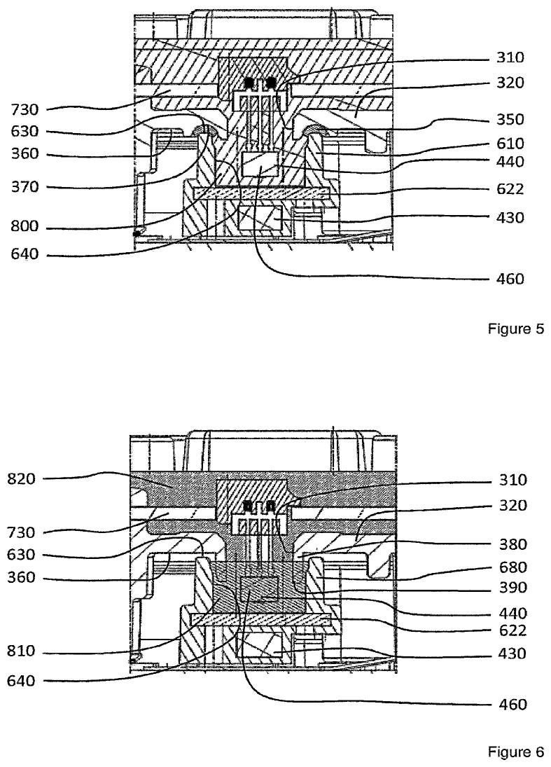

FIG. 5 shows a partial sectional view of an electronic system according to a first embodiment of the invention,

FIG. 6 shows a partial sectional view of an electronic system according to a second embodiment of the invention,

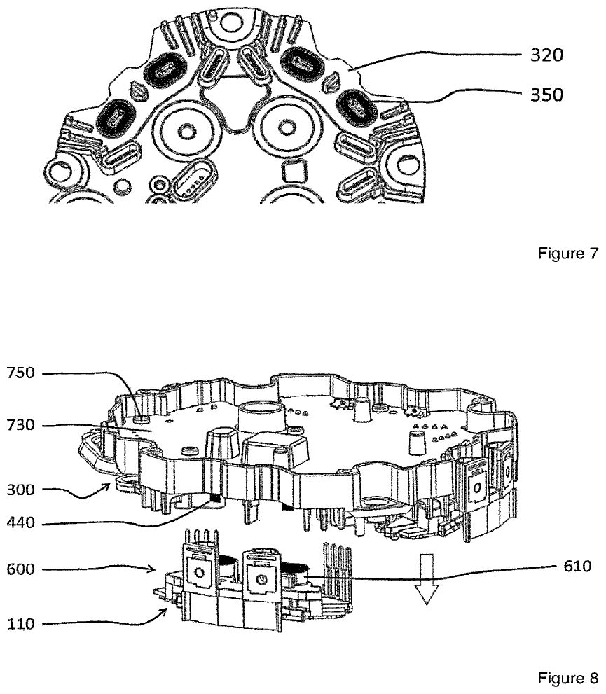

FIG. 7 shows a first step of assembling the electronic module of FIG. 5,

FIG. 8 shows a second step of assembling the electronic module of FIG. 5,

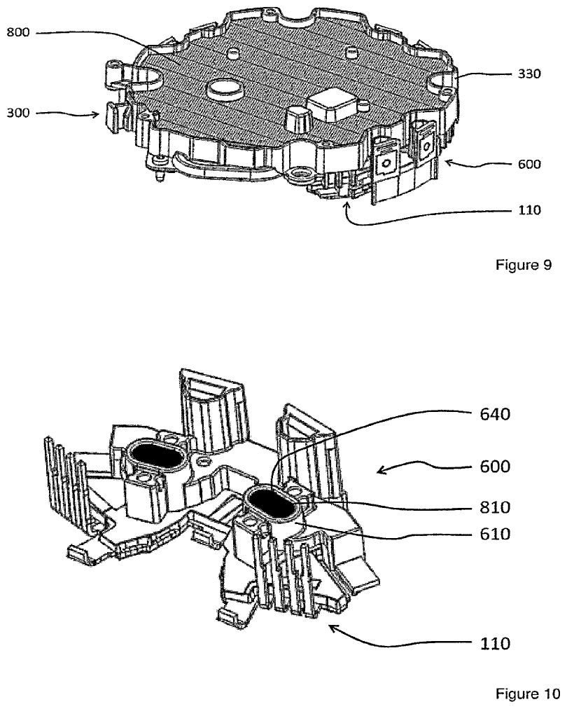

FIG. 9 shows a third step of assembling the electronic module of FIG. 5,

FIG. 10 shows a first step of assembling the electronic module of FIG. 6,

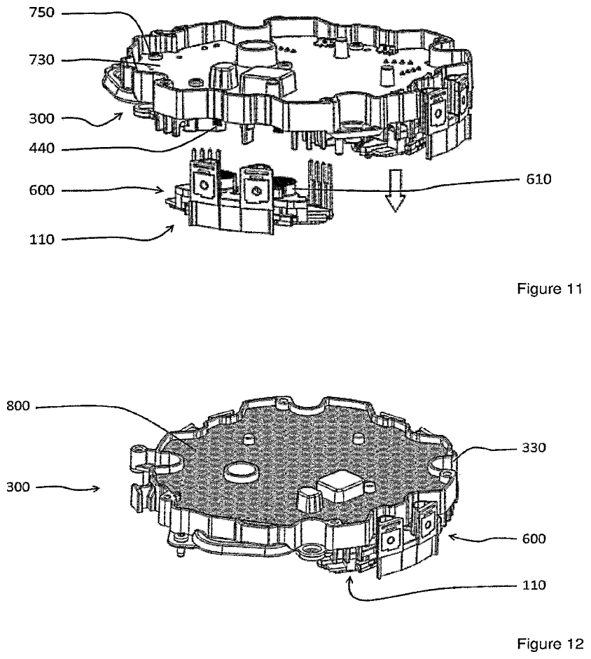

FIG. 11 shows a second step of assembling the electronic module of FIG. 6,

FIG. 12 shows a third step of assembling the electronic module of FIG. 6.

In all of the figures, elements that are identical or perform the same function bear the same reference numerals. The following embodiments are examples. Although the description refers to one or more embodiments, this does not necessarily mean that each reference sign relates to the same embodiment, or that the features only apply to just one embodiment. Individual features of various embodiments may also be combined or interchanged in order to create other embodiments.

FIG. 1 shows an electrical assembly 100 in which the invention may be implemented.

The electrical assembly 100 is for example intended to be installed in a motor vehicle.

The electrical assembly 100 firstly comprises an electric power source 102 designed to deliver a DC voltage U, for example between 20 V and 100 V, for example 48 V. The electric power source 102 comprises for example a battery.

The electrical assembly 100 furthermore comprises a rotating electric machine 130 comprising a plurality of phase windings (not shown) that are intended to have respective phase voltages.

The electrical assembly 100 furthermore comprises an electronic system 104.

In the various embodiments shown in the figures, the electronic system 104 is a voltage converter 104. However, in other embodiments that are not shown, the assembly may perform a different function.

The voltage converter 104 is connected between the electric power source 102 and the electric machine 130 in order to perform a conversion between the DC voltage U and the phase voltages.

The voltage converter 104 firstly comprises a positive electric line 106 and a negative electric line 108 that are intended to be connected to the electric power source 102 in order to receive the DC voltage U, with the positive electric line 106 receiving a high electric potential and the negative electric line 108 receiving a low electric potential. The negative electric line receives a zero potential for example, and is connected to a ground of the motor vehicle.

The voltage converter 104 furthermore comprises at least one power electronics module 110 comprising one or more phase electric lines 122 that are intended to be respectively connected to one or more phases of the electric machine 130 in order to provide their respective phase voltages.

In the example described, the voltage converter 104 comprises three power electronics modules 110, each comprising two phase electric lines 122 connected to two phases of the electric machine 130.

More specifically, in the example described, the electric machine 130 comprises two three-phase systems each comprising three phases and intended to be electrically phase-shifted from one another by 120°. Preferably, the first phase electric lines 122 of the power electronics modules 110 are respectively connected to the three phases of the first three-phase system, whereas the second phase electric lines 122 of the power electronics modules 110 are respectively connected to the three phases of the second three-phase system.

Each power electronics module 110 comprises, for each phase electric line 122, a first controllable switch 112 connected between the positive electric line 106 and the phase electric line 122 and a second controllable switch 114 connected between the phase electric line 122 and the negative electric line 108. The controllable switches 112, 114 are thus arranged so as to form a chopping arm, in which the phase electric line 122 forms a center tap.

Each controllable switch 112, 114 comprises first and second main terminals 116, 118 and a control terminal 120 intended to selectively open and close the controllable switch 112, 114 between its two main terminals 116, 118 depending on a control signal that is applied thereto. The controllable switches 112, 114 are preferably transistors, for example Metal-Oxide-Semiconductor Field-Effect Transistors (MOSFETs) having a gate forming the control terminal 120, and a drain and a source respectively forming the main terminals 116, 118.

In the example described, the controllable switches 112, 114 each have the form of a plate that is for example substantially rectangular and that has an upper face and a lower face. The first main terminal 116 extends over the lower face, whereas the second main terminal 118 extends over the upper face. Furthermore, the lower face forms a heat dissipation face.

The voltage converter 104 furthermore comprises, for each power electronics module 110, a filtering capacitor 124 having a first terminal 126 and a second terminal 128 respectively connected to the positive electric line 106 and to the negative electric line 108.

It will be appreciated that the positive electric line 106, the negative electric line 108 and the phase electric lines 122 are rigid elements designed to withstand electric currents of at least 1 A. They preferably have a thickness of at least 1 mm.

Furthermore, in the example described, the electric machine 130 simultaneously has an alternator and electric motor function. More specifically, the motor vehicle furthermore comprises a combustion engine (not shown) having an output shaft, to which the electric machine 130 is connected, for example, via a belt or via a chain or via a geartrain (not shown). The combustion engine is intended to drive wheels of the motor vehicle by way of its output shaft. Thus, during operation as an alternator, the electric machine supplies the electric power source 102 with electrical energy based on the rotation of the output shaft. The voltage converter 104 then operates as a rectifier. During operation as an electric motor, the electric machine drives the output shaft (in addition to or else instead of the combustion engine). The voltage converter 104 then operates as an inverter.

The electric machine 130 is located for example in a gearbox or else in a clutch of the motor vehicle or else in place of the alternator.

FIG. 2 shows an electronic system 104 according to the invention.

The electronic system 104 comprises:
a power electronics module 110 for converting a DC current to an AC current, the power electronics module 110 comprising:
   a first busbar 206 and a second busbar 208 for supplying the power electronics module 110 with the DC current,
   a third busbar 522 able to supply a phase winding of the rotating electric machine 130,
   a control pin 520 receiving a control signal for driving the power electronics module 110.

The first busbar 206 is electrically connected to the positive electric line 106. The second busbar 208 is electrically connected to the negative electric line 108. The third busbar 522 is electrically connected to the phase electric line 122. The control pin 150 is electrically connected to the control terminal 120.

The power electronics module 110 may furthermore comprise a first casing 550 overmolded onto the first controllable switch 112, the second controllable switch 114, the first busbar 206, the second busbar 208, the third busbar 522 and the control pin 150. The power electronics module is for example produced using TML (Transfer Molded Leadframe) technology. The electrical insulator is for example a thermosetting resin of epoxy type.

In another embodiment that is not shown, the power electronics module furthermore comprises a first casing overmolded onto the first busbar, the second busbar, the third busbar and the control pin. The first controllable switch and the second controllable switch are electrically connected to the first busbar, the second busbar, the third busbar and the control pin but are not overmolded in the first casing. For example, a protective gel is deposited in the casing so as to protect the first controllable switch and the second controllable switch along with their connections to the first busbar, to the second busbar and to the control pin.

The electrical system 104 may furthermore comprise a heat sink (not shown).

The power electronics module 110 is fastened to the heat sink by way of a fastening means.

The power electronics module 110 comprises a heat dissipation surface. This heat dissipation surface is in thermal contact with a heat exchange surface of the heat sink. The thermal contact is for example made using a thermal paste or a thermal adhesive.

The electronic system furthermore comprises:
an electronic control module 700 separate from the power electronics module and configured so as to generate the control signal, the electronic control module 700 comprising an electronic measuring device 440,
a support 300 comprising an opening 310 and carrying the electronic control module 700 on a first side 320 of the support 300,
a measurement housing 600 comprising a cavity 640, the measurement housing 600 being located on a second side 360 of the support 300 opposite the first side 320 of the support 300.

The electronic measuring device 440 penetrates into the opening 310 in the support 300 and into the cavity 640 in the measurement housing 600.

The support 300 is for example made of metal, in particular an aluminum alloy.

The support 300 defines a receptacle 390 with a bottom wall 340 and a rim 330. The electronic control module 700 is housed in the receptacle 390. The bottom wall 340 is for example generally flat. The rim 330 has for example a generally tubular shape that projects from the bottom wall 340 on the side of the electronic control module 700.

The electronic control module 700 comprises for example an electronic board 730 and electronic components connected to the electronic board 730. The electronic measuring device 440 is for example connected to the electronic board 730 and is fastened to the electronic board 730 in holes 740, for example oblong holes, formed in the electronic board 730.

The electronic control module 700 may comprise a heat dissipation surface. This heat dissipation surface is in thermal contact with a heat exchange surface of the support 300, for example a heat exchange surface of the bottom wall 340. The thermal contact is for example made using a thermal paste or a thermal adhesive.

The use of a metal support 300 makes it possible to improve the cooling of the electronic control module 700.

FIG. 3 and FIG. 4 show the measurement housing 600.

In the embodiment shown, the measurement housing 600 is an interconnection module. It provides the electrical connection between the third busbar 522 and the phase winding of the electric machine 130. The measurement housing 600 comprises a conductor 622. The conductor 622 is connected for example, at one of these ends, to the third busbar 522 and, at another of these ends, to the phase winding of the machine 130.

The measurement housing 600 shown in FIG. 3 and FIG. 4 comprises two conductors 622 for connecting two third busbars 522 to two phase windings of the electric machine 130. Each of the two conductors 622 is connected to a third busbar and able to be connected to a phase winding of the machine 130.

The connection between the conductor 622 and the third busbar 522 is for example made by welding, such as electric welding, laser welding or brazing.

The connection between the conductor 622 and the phase winding is for example made by screwing. To improve the screw connection, a nut 660 may be fastened to the conductor 62, for example by welding or press-fitting.

The measurement housing 600 may furthermore comprise a magnetic toroid 430. The electrical conductor 622 passes through the magnetic toroid 430. The electronic measuring device 440 may comprise a Hall effect sensor 460. The magnetic toroid 430 has an air gap 450. The cavity 640 in the measurement housing 600 penetrates into the air gap 450. The Hall effect sensor 460 of the measuring device 440 is inserted into the cavity 640 in the measurement housing 600. The magnetic toroid 430 and the Hall effect sensor interact so as to measure the current in the electrical conductor 622.

The measurement housing 600 comprises a second casing 620 overmolded onto the electrical conductor 622 and the toroid 430.

In another embodiment that is not shown, the measurement housing is formed in the power electronics module. One of the busbars of the power electronics module, in particular the third busbar, passes through the magnetic toroid. In this embodiment, the power electronics module and the measurement housing are contiguous. For example, the first overmolded casing 550 and the second overmolded casing 620 form one and the same casing.

FIG. 5 shows a first embodiment of the invention.

In this embodiment, the measurement housing 600 comprises a chimney 610, comprising a first free end 630. The chimney 610 surrounds an open end of the cavity 640. The support 300 comprises a groove 370 facing the first free end 630 of the chimney 610 of the measurement housing 600.

A sealing means provides a seal between the measurement housing 600 and the support 300. The sealing means is for example a seal 350 inserted into the groove 370. The seal is for example an adhesive deposit.

A protective means 800, in particular a gel or a protective resin, for example a polymerizable one, fills the receptacle 390 so as to cover the electronic control module 700.

The protective means 800 also fills the opening 310 in the support and the cavity 640 in the measurement housing 600.

The term fill is understood to mean that the protective means 800 prevents liquid or other contaminating elements from intruding on the electronic control module 700, and in particular on the electronic measuring device 440. It may be acceptable for some areas of the receptacle 390, of the opening 310 and of the cavity 640 not to contain protective means. These areas, such as bubbles, may be generated when filling the receptacle 390, the opening 310 and the cavity 640.

The sealing means prevents the protective means 800 from flowing between the measurement housing 600 and the support 300.

In another embodiment of the invention that is not shown, the support comprises a chimney, comprising a first free end. The chimney surrounds the opening in the support on the second side of the support, and the measurement housing comprises a groove facing the first free end of the chimney. As in the first embodiment, the sealing means between the measurement housing and the support is for example a seal, in particular an adhesive deposit, inserted into the groove.

In another embodiment that is not shown, the measurement housing comprises a chimney comprising a first free end of a first shape. The chimney surrounds an open end of the cavity. The support comprises a bearing surface of a second shape, complementary to the first shape, facing the first free end of the chimney of the measurement housing. The first shape of the first free end of the chimney bears against the second shape of the bearing surface of the support directly or by way of a seal arranged between the first free end and the bearing surface. Such a seal is for example an adhesive deposit. The first shape and the second shape are for example planes.

In another embodiment that is not shown, the support comprises a chimney comprising a first free end of a first shape. The chimney surrounds the opening in the support on the second side of the support. The measurement housing comprises a bearing face of a second shape, complementary to the first shape, facing the first free end of the chimney of the support. The first shape of the first free end of the support bears against the second shape of the bearing face of the measurement housing directly or by way of a seal arranged between the first free end and the bearing surface.

In another embodiment that is not shown, the support comprises a first chimney comprising a first free end of a first shape. The first chimney surrounds the opening in the support on the second side of the support. The measurement housing comprises a second chimney, comprising a second free end of a second shape complementary to the first shape. The second chimney surrounds an open end of the cavity. The second free end of the second chimney of the measurement housing faces the first free end of the first chimney of the support. The first shape of the first chimney of the support bears against the second shape of the second chimney of the measurement housing directly or by way of a seal arranged between the first shape of the first chimney of the support and the second shape of the second chimney of the measurement housing.

FIG. 6 shows a second embodiment of the invention.

In this embodiment, the support 300 comprises a first tubular protuberance 380 surrounding the opening 310 in the support 300 on the second side 360 of the support 300. The first tubular protuberance 380 comprises a second free end 390. The measurement housing 600 comprises a second tubular protuberance 680 at least partially around the cavity 640. The first tubular protuberance 380 penetrates into the second tubular protuberance 680. A sealing device is arranged between the first tubular protuberance 380 and the second tubular protuberance 680.

The sealing device is for example a resin 810 that is poured into the cavity 640 and then polymerized. The amount of resin 810 is sufficient for the second free end 390 to be immersed in the resin.

The second free end 390 is for example immersed in the resin 810 by from 0.5 mm to 10 mm and preferably by from 1 mm to 2 mm.

The Hall effect sensor 460 is immersed in the resin 810.

The Hall effect sensor 460 protrudes for example out of the first tubular protuberance 380 so as to avoid the measurements of the Hall sensor 460 being interfered with by the first tubular protuberance 380.

In another embodiment that is not shown and similar to the second embodiment, the seal is not provided by a polymerized resin in the cavity 640, but by a seal arranged between the first tubular protuberance 380 and the second tubular protuberance 680. The seal is for example an elastic sleeve inserted into the second tubular protuberance 680 or an elastic sleeve arranged outside the first tubular protuberance 380.

FIG. 7, FIG. 8 and FIG. 9 show steps of assembling the electronic system 104 according to the first embodiment.

FIG. 7 shows a first assembly step in which the seal 350 is deposited in the groove 370 of the support 300.

The seal 350 is for example placed in the groove 370 or is deposited in the form of a paste using a nozzle (not shown).

FIG. 8 shows a second assembly step in which the measurement housing 600 and the support 300 are assembled, the electronic control module 700 having been mounted in the receptacle 390 in the support 300.

At the end of this step, the seal 350 provides the seal between the first free end 630 of the chimney 610 of the measurement housing 600 and the groove 370 of the support 300.

FIG. 9 shows a third assembly step in which the protective means 800 is poured into the receptacle 390 in the support 300 on the electronic control module 700. The protective means flows into interstices between the support 300 and the electronic control module 700. The protective means 800 thus flows under the control module 700 as far as the opening 310 in the support, and then into the cavity 640 in the measurement housing 600.

Any flow between the first free end 630 and the groove 370 is prevented by the seal 350.

FIG. 10, FIG. 11 and FIG. 12 show steps of assembling the electronic system 104 according to the second embodiment.

FIG. 10 shows a first assembly step in which the resin 810 is poured into the cavity 640 in the measurement housing 600.

FIG. 11 shows a second assembly step in which the measurement housing 600 and the support 300 are assembled, the electronic control module 700 having been mounted in the receptacle 390 in the support 300.

The first tubular protuberance 380 penetrates into the resin 810.

The resin 810 polymerizes. For example, the resin 810 polymerizes under the effect of an external heat input or the resin 810 is a self-polymerizing resin, that is to say a resin capable of polymerizing at room temperature.

At the end of this step, the resin 810 forms a seal between the first tubular protuberance 380 and the second tubular protuberance 680. The Hall effect sensor 460 is surrounded by the resin 810.

FIG. 12 shows a third assembly step in which the protective means 820 is poured into the receptacle 390 in the support 300 on the electronic control module 700. The protective means 820 flows into interstices between the support 300 and the electronic control module 700. The protective means 820 thus flows under the control module 700 as far as the opening 310 in the support. The flow of the protective means 820 into the cavity 640 is blocked by the resin 810.

1. An electronic system comprising:
a. a power electronics module for converting a DC current to an AC current, the power electronics module comprising:
i. a first busbar and a second busbar for supplying the power electronics module with the DC current,
ii. a third busbar able to supply a phase winding of a rotating electric machine,
iii. a control pin receiving a control signal for driving the power electronics module,
b. an electronic control module separate from the power electronics module and configured so as to generate the control signal, the electronic control module comprising an electronic measuring device,
c. a support comprising an opening and carrying the electronic control module on a first side of the support, the support being in particular made of metal,
d. a measurement housing comprising a cavity, the measurement housing being located on a second side of the support opposite the first side of the support,
the electronic measuring device penetrating into the opening in the support and into the cavity in the measurement housing,
a sealing means providing a seal between the measurement housing and the support.

2. The electronic system as claimed in claim 1, wherein the electronic module comprises a first casing overmolded onto the first busbar, the second busbar, the third busbar and the control pin, and wherein the measurement housing is formed contiguously with the first overmolded casing of the power electronics module.

3. The electronic system as claimed in claim 1, wherein the measurement housing comprises a chimney, comprising a first free end, surrounding an open end of the cavity, and the support comprises a groove facing the first free end of the chimney of the measurement housing.

4. The electronic system as claimed in claim 1, wherein the support comprises a chimney, comprising a first free end, surrounding the opening in the support on the second side of the support, and the measurement housing comprises a groove facing the first free end of the chimney.

5. The electronic system as claimed in claim 3, wherein a seal inserted into the groove provides the seal between the measurement housing and the support.

6. The electronic system as claimed in claim 5, wherein the seal is an adhesive deposit.

7. The electronic system as claimed in claim 1, wherein:
a. either the measurement housing comprises a chimney, comprising a first free end of a first shape, surrounding an open end of the cavity, and the support comprises a bearing surface of a second shape, complementary to the first shape, facing the first free end of the chimney of the measurement housing,
b. or the support comprises a chimney, comprising a first free end of a first shape, surrounding the opening in the support on the second side of the support, and the measurement housing comprises a bearing face of a second shape, complementary to the first shape, facing the first free end of the chimney of the support,
c. or the support comprises a first chimney, comprising a first free end of a first shape, surrounding the opening in the support on the second side of the support, and the measurement housing comprises a second chimney, comprising a second free end of a second shape complementary to the first shape, surrounding an open end of the cavity, the second free end of the second chimney of the measurement housing facing the first free end of the first chimney of the support,
a seal being arranged between the first shape of the support and the second shape of the measurement housing.

8. The electronic system as claimed in claim 1, wherein the support comprises a first tubular protuberance surrounding the opening in the support on the second side of the support, and the measurement housing comprises a second tubular protuberance at least partially around the cavity, the first tubular protuberance penetrating into the second tubular protuberance.

9. The electronic system as claimed in claim 8, wherein a sealing device is arranged between the first tubular protuberance and the second tubular protuberance.

10. The electronic system as claimed in claim 9, wherein the sealing device is a resin that is poured into the cavity and then polymerized.

11. The electronic system as claimed in claim 1, wherein the measurement housing comprises a magnetic toroid having an air gap, and the electronic measuring device comprises a Hall effect sensor inserted into the cavity in the measurement housing and the air gap, the magnetic toroid and the Hall effect sensor interacting so as to measure the current of an electrical conductor passing through the magnetic toroid.

12. The electronic system as claimed in claim 11, wherein the electrical conductor is electrically connected to the third busbar.

13. The electronic system as claimed in claim 11, wherein the measurement housing is overmolded onto the electrical conductor and/or the measurement housing is overmolded onto the magnetic toroid.

14. The electronic system as claimed in claim 1, wherein the support defines a receptacle with a bottom wall in which the opening is formed, the electronic control module is housed in the receptacle and a gel or a protective resin fills the receptacle so to cover the electronic control module.

15. An electrical assembly comprising:
a. an electronic system as claimed in claim 1,
b. a rotating electric machine.

16. The electronic system as claimed in claim 2, wherein the measurement housing comprises a chimney, comprising a first free end, surrounding an open end of the cavity, and the support comprises a groove facing the first free end of the chimney of the measurement housing.

17. The electronic system as claimed in claim 2, wherein the support comprises a chimney, comprising a first free end, surrounding the opening in the support on the second side of the support, and the measurement housing comprises a groove facing the first free end of the chimney.

18. The electronic system as claimed in claim 4, wherein a seal inserted into the groove provides the seal between the measurement housing and the support.

19. The electronic system as claimed in claim 2, wherein:
a. either the measurement housing comprises a chimney, comprising a first free end of a first shape, surrounding an open end of the cavity, and the support comprises a bearing surface of a second shape, complementary to the first shape, facing the first free end of the chimney of the measurement housing,
b. or the support comprises a chimney, comprising a first free end of a first shape, surrounding the opening in the support on the second side of the support, and the measurement housing comprises a bearing face of a second shape, complementary to the first shape, facing the first free end of the chimney of the support,
c. or the support comprises a first chimney, comprising a first free end of a first shape, surrounding the opening in the support on the second side of the support, and the measurement housing comprises a second chimney, comprising a second free end of a second shape complementary to the first shape, surrounding an open end of the cavity, the second free end of the second chimney of the measurement housing facing the first free end of the first chimney of the support,
a seal being arranged between the first shape of the support and the second shape of the measurement housing.

20. The electronic system as claimed in claim 2, wherein the support comprises a first tubular protuberance surrounding the opening in the support on the second side of the support, and the measurement housing comprises a second tubular protuberance at least partially around the cavity, the first tubular protuberance penetrating into the second tubular protuberance.
